(19) United States
(12) Patent Application Publication
(10) Pub. No.: US 2026/0031300 A1
(43) Pub. Date: Jan. 29, 2026

(54) STANDARD SAMPLE FOR USE IN TRANSMISSION ELECTRON MICROSCOPE, METHOD OF PREPARING THE SAME, METHOD OF ADJUSTING TRANSMISSION ELECTRON MICROSCOPE, AND METHOD OF ANALYZING OBSERVATION IMAGE OBTAINED WITH TRANSMISSION ELECTRON MICROSCOPE

(71) Applicant: Hitachi, Ltd., Chiyoda-ku, Tokyo (JP)

(72) Inventors: Kumi MOTAI, Chiyoda-ku, Tokyo (JP); Hirokazu TAMAKI, Chiyoda-ku, Tokyo (JP)

(21) Appl. No.: 18/994,301

(22) PCT Filed: Jan. 20, 2023
(86) PCT No.: PCT/JP2023/001675

§ 371 Date: Jan. 14, 2025

(30) Foreign Application Priority Data
Aug. 8, 2022 (JP) 2022-126140

(51) Int. Cl. H01J 37/26; G01N 1/28; G01N 1/32; H01J 37/305

(52) U.S. Cl. CPC H01J 37/263; G01N 1/32; H01J 37/3056; G01N 2001/2893; H01J 2237/2826; H01J 2237/31745; H01J 2237/31749

(57) ABSTRACT

To provide a standard sample for use in a transmission electron microscope capable of easily setting observation conditions that emphasize the contrast of an observation image, and a method of preparing the standard sample. The standard sample for use in the transmission electron microscope, includes: a film stack that is formed by stacking a plurality of materials on a surface of an observation sample to be observed with the transmission electron microscope; and an observation surface that is a plane intersecting the surface of the observation sample and being connected to the observation sample. A thickness in a direction orthogonal to the observation surface is thinned.

### TECHNICAL FIELD

The present invention relates to a standard sample for use in adjusting the observation conditions of a transmission electron microscope and a method of preparing the standard sample.

### BACKGROUND TECHNOLOGY

As semiconductor devices are becoming finer, a transmission electron microscope (TEM) having higher spatial resolution than a scanning electron microscope (SEM) is being used in semiconductor device manufacturing steps and the like. Since TEM includes a larger number of condenser lenses than SEM and the condenser lenses have an aberration, it takes time to set observation conditions including aberration adjustment in order to obtain an accurate observation image.

Patent Literature 1 discloses a method of irradiating a joined body of an observation sample to be observed with TEM and a standard sample having a known lattice constant with electron beams from a side of the joined body to include the observation sample and the standard sample in an irradiation spot and thereby obtaining the respective images of these samples simultaneously. This means that the same degree of an aberration of a condenser lens appears in the simultaneously obtained images of these samples and the influence of the aberration can be offset by making use of the image of the standard sample for the evaluation of the observation sample so that the observation sample can be evaluated more accurately.

### CITATION LIST

### Patent Literature

Patent Literature 1: Japanese Unexamined Patent Application Publication No. 2005-195353

### SUMMARY OF INVENTION

### Technical Problem

Patent Literature 1 however does not include consideration on emphasizing the contrast of the observation image. The contrast of the observation image depends on the average atomic number of materials contained in the observation sample and for example, in an observation sample containing two phases having relatively close average atomic numbers such as Si₃N₄ and SiO₂ or HfC and HfO₂, it becomes difficult to detect a boundary between these two phases because of a decrease in the contrast of the two phases.

An object of the present invention is therefore to provide a standard sample for use in a transmission electron microscope capable of easily setting observation conditions that emphasize the contrast of an observation image, and a method of preparing the standard sample.

### Solution to Problem

In order to achieve the above object, the present invention provides a standard sample for use in a transmission electron microscope, and the standard sample includes: a film stack that is formed by stacking a plurality of materials on a surface of an observation sample to be observed with the transmission electron microscope; and an observation surface that is a plane intersecting the surface of the observation sample and being connected to the observation sample.

Further, the present invention provides a method of preparing a standard sample for use in a transmission electron microscope, and the method includes: a stacking step in which a plurality of materials is stacked on a surface of an observation sample to be observed with a transmission electron microscope; an observation surface formation step in which an observation surface that is a plane intersecting the surface of the observation sample and being connected to the observation sample is formed; and a film thinning step in which a thickness in a direction orthogonal to the observation surface is thinned.

### Advantageous Effects of Invention

According to the present invention, it is possible to provide a standard sample for use in a transmission electron microscope capable of easily setting observation conditions that emphasize the contrast of an observation image, and a method of preparing the standard sample.

### BRIEF DESCRIPTION OF DRAWINGS

FIG. 1 shows a standard sample prepared on an observation sample.

FIG. 2 is a perspective view showing a constitution example of a standard sample of the present invention.

FIGS. 3A-3G show one example of a method of preparing the standard sample of the present invention.

FIGS. 4A and 4B show other constitution examples of the standard sample of the present invention.

FIGS. 5A and 5B show one example of data obtained using the standard sample of the present invention.

### DESCRIPTION OF EMBODIMENTS

The standard sample for use in a transmission electron microscope and the method of preparing the standard sample according to the present invention will hereinafter be described referring to some drawings. The transmission electron microscope (TEM) is a device that irradiates a sample with electron beams, detects the electrons that have passed through the sample, and thereby forms an observation image for observing the sample. The contrast of the observation image obtained with TEM depends on the average atomic number of a material contained in the observation sample. Both a TEM image and a STEM image can be obtained with TEM. The STEM includes DF-STEM (Dark Field-Scanning TEM), BF-STEM (Bright Field-STEM), ABF-STEM (Annular BF-STEM), and the like. The contrast of the observation image obtained with DF-STEM particularly depends on the average atomic number. The average atomic number Zave can be calculated, for example, by the following equation:

$$Zave = \sum ( Ci \cdot Zi ) \qquad ( Equation 1 )$$

wherein Ci is the atomic concentration of the i-th atom contained in an observation sample, Zi is the atomic number of the i-th atom contained in the observation sample, and i is a natural number and the value of Ci falls within a range of 0 to 1.

Using the (Equation 1), the average atomic numbers of Si₃N₄, SiO₂, HfC, and HfO₂ are calculated to be 11.2, 10.8, 67.8, and 62.3, respectively. A difference between Si₃N₄ and SiO₂ and a difference between HfC and HfO₂ are both less than 10% and are relatively close to each other. This means that if the observation sample contains Si₃N₄ and SiO₂ or HfC and HfO₂, the contrast of the observation image becomes small. Observation conditions that emphasize the contrast are therefore set using a standard sample and the observation conditions thus set are applied to the observation sample.

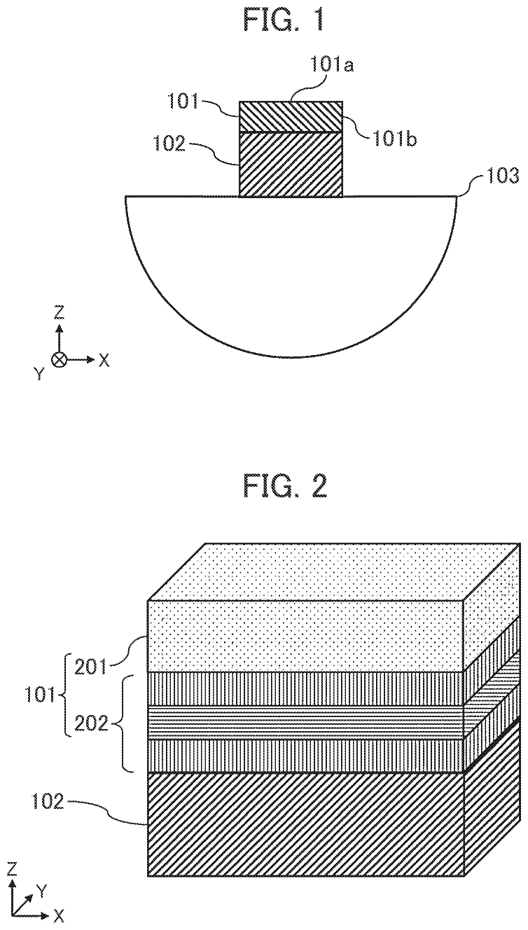

A standard sample 101 and an observation sample 102 will next be described referring to FIG. 1. The standard sample 101 is formed on the observation sample 102 to be observed with TEM. It is to be noted that the observation sample 102 is placed on a sample holder 103 having a half-round shape. The sample holder 103 having a half-round shape can rotate with an axis parallel to the Y axis as a rotation axis. It is to be noted that when the observation sample 102 is observed with TEM, it is irradiated with electron beams in parallel to the Y axis so that an observation surface, which is a plane irradiated with the electron beams, has thereat both the observation sample 102 and the standard sample 101 connected to each other. Since the observation sample 102 and the standard sample 101 are connected to each other at the observation surface, a variation in observation conditions due to visual field movement, which occurs when the observation conditions set using the standard sample 101 are applied to the observation sample 102, can be made relatively smaller.

The constitution example of the standard sample 101 will next be described referring to FIG. 2. FIG. 2 shows the standard sample 101 having a film stack 202 and a protection film 201.

The film stack 202 is obtained by stacking a plurality of materials on the surface of the observation sample 102. The film stack 202 shown in FIG. 2 has a three-layer structure in which the first layer and the third layer are made of the same material and the material of the second layer is different from that of the first layer and the third layer. The film stack 202 is not limited to have three layers and it may have either two layers or four layers or more.

The materials constituting the film stack 202 are preferably relatively close in average atomic number. For example, Si₃N₄ and SiO₂ may be stacked one after another or HfC and HfO₂ may be stacked one after another. Using the standard sample 101 having the film stack 202 composed of materials relatively close in average atomic number for setting of observation conditions makes it easy to set the observation conditions that emphasize the contrast.

The material constituting the film stack 202 is preferably a material contained in the observation sample 102. Applying the observation conditions set using the standard sample 101 having the film stack 202 composed of the material contained in the observation sample 102 to the observation sample 102 makes it easy to emphasize the contrast of an observation image more.

Further, the thickness of the film stack 202 is preferably equal to or larger than the spot diameter of the electron beams irradiated by TEM. The film stack 202 having a thickness equal to or larger than the spot diameter of the electron beams facilitates setting of the observation conditions that emphasize the contrast.

The protection film 201 is provided for protecting the film stack 202 or the observation sample 102. It is to be noted that the protection film 201 is not essential. Alternatively, the film stack 202 may function as a film for protecting the observation sample 102.

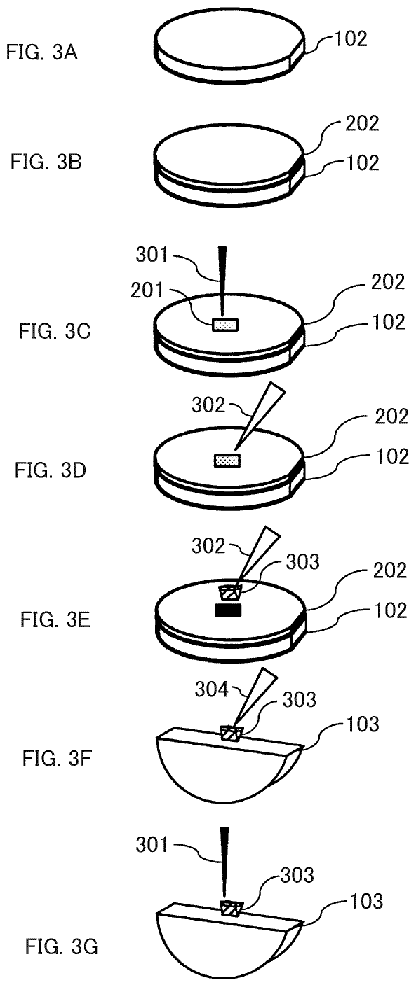

One example of a method of preparing the standard sample 101 will next be described referring to FIGS. 3A-3G. First, as shown in FIG. 3A, a wafer is provided as the observation sample 102.

Next, as shown in FIG. 3B, a film stack 202 is formed on the surface of the observation sample 102. The film stack 202 may be formed using an atomic layer deposition device or focused ion beams. Since the film stack 202 formed using the atomic layer deposition device has high film-thickness accuracy, the film thickness of the film stack 202 can be utilized for magnification calibration of the observation image. On the other hand, when TEM capable of emitting focused ion beams is used, the film stack 202 can be formed using the focused ion beams so that it is not necessary to provide a device such as atomic layer deposition device in advance.

Next, as shown in FIG. 3C, the film stack 202 formed on the surface of the observation sample 102 is irradiated with the focused ion beams 301. The focused ion beams 301 are scanned around a region presumed to be the standard sample 101. It is to be noted that prior to the irradiation with the focused ion beams 301, the protection film 201 may be provided on the surface of the film stack 202 in order to protect the film stack 202 and the observation sample 102 from the focused ion beams 301. The film stack 202 has an area wider than a field scanned with the focused ion beams 301.

Next, as shown in FIG. 3D, a metal probe 302 is bonded to a region which is presumed to be the standard sample 101. The focused ion beams 301 may be used for bonding of the metal probe 302. Described specifically, a reaction between an atmospheric gas and the metal probe 302 is caused by means of the focused ion beams 301 to bond the metal probe 302 to the region presumed to be the standard sample 101.

Next, as shown in FIG. 3E, a sample piece 303 which is the region presumed to be the standard sample 101 is taken out by the metal probe 302.

Next, as shown in FIG. 3F, the sample piece 303 taken out by the metal probe 302 is fixed onto the sample holder 103. The focused ion beams 301 may be used for fixing the sample piece 303 to the sample holder 103.

Finally, as shown in FIG. 3G, the sample piece 303 is shaven at the side surface thereof, for example, by the focused ion beams 301, to thin the piece to allow electron beams to pass therethrough. Alternatively, plasma may be used for thinning the sample piece 303. The side surface of the thinned sample piece 303 becomes an observation surface in which the observation sample 102, the film stack 202, and the protection film 201 are connected to one another.

When the film stack 202 and the observation sample 102 are irradiated with the focused ion beams 301 from a direction orthogonal to their surfaces, the observation surface is a plane orthogonal to the surfaces of the film stack 202 and the observation sample 102, and the thickness of the sample piece 303, that is, a distance between the side surfaces can be adjusted with high accuracy. It is to be noted that the observation surface should intersect the surfaces of the film stack 202 and the observation sample 102 and is not necessarily orthogonal to them.

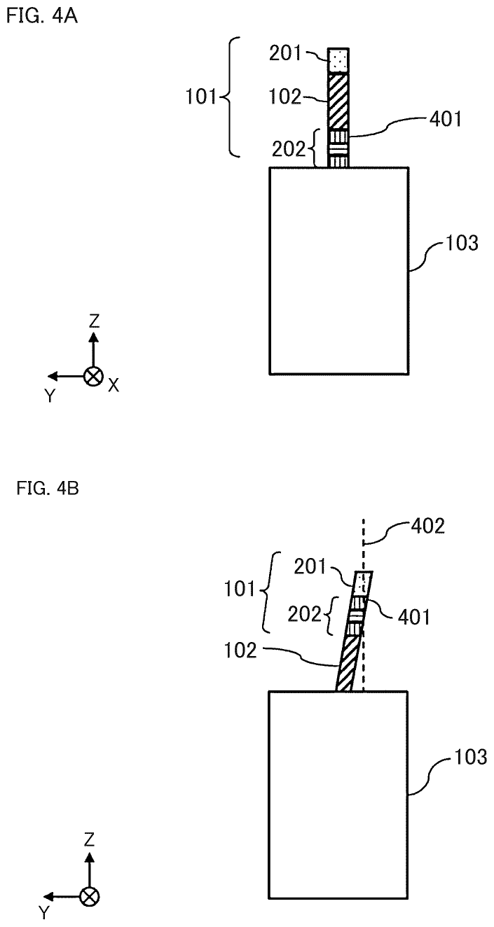

Other constitution examples of the standard sample 101 will next be described referring to FIGS. 4A and 4B. The standard sample 101 shown in FIG. 4A has the observation sample 102 and the protection film 201 on the film stack 202. Even from the standard sample 101 shown in FIG. 4B, a contrast-emphasized observation image can be obtained by applying, to the observation sample 102, observation conditions set using the film stack 202. It is to be noted that such a standard sample 101 is formed by turning the observation sample 102, which has the film stack 202 formed on the surface thereof as shown in FIG. 3B, upside down and then irradiating it with the focused ion beams 301 as shown in FIG. 3C.

The standard sample 101 shown in FIG. 4B has an observation surface 401 which intersects the surfaces of the film stack 202 and the observation sample 102 but does not intersect them perpendicularly. This means that the observation surface 401 shown in FIG. 4A is inclined with respect to an orthogonal plane 402 which is orthogonal to the surfaces of the film stack 202 and the observation sample 102. By inclining the observation surface 401 with respect to the orthogonal plane 402 which is orthogonal to the surface of the observation sample 102, the thickness of the film stack 202 at the observation surface 401 can be made larger even if the thickness of the film stack 202 is relatively small. This offers advantages, including easier observation using a secondary electron image. The standard sample 101 as described above is formed, in the film thinning step of the sample piece 303, by emitting the focused ion beams 301 with an inclination with respect to a direction orthogonal to the surfaces of the film stack 202 and the observation sample 102.

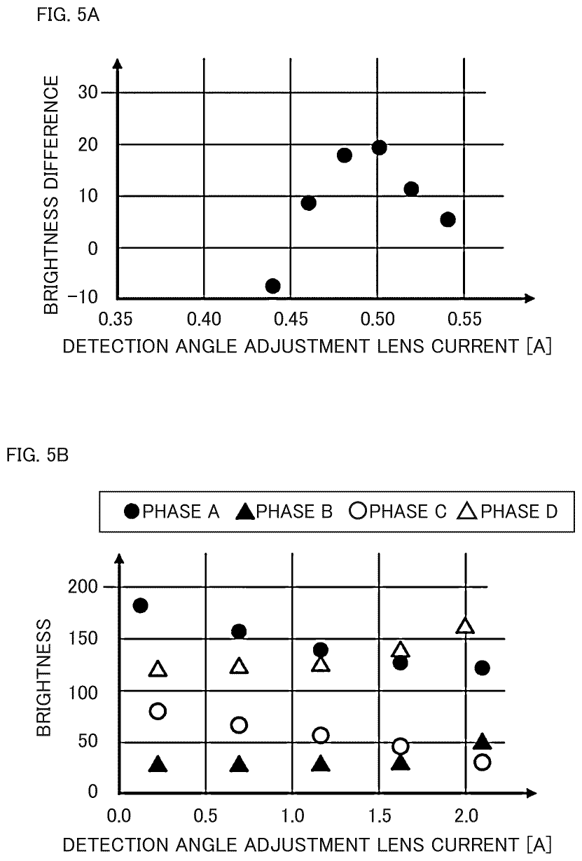

Next, adjustment of observation conditions to be applied to the observation sample 102 or analysis of an observation image, each based on the data obtained using the standard sample 101, will be described referring to FIGS. 5A and 5B. The graph shown in FIG. 5A includes data showing the relationship between a brightness difference, that is, a difference in brightness between two phases contained in the STEM image of the standard sample 101 and a detection angle adjustment lens current. The “detection angle adjustment lens current” is one of the observation conditions and it means a current to be applied to a detection angle adjustment lens, which is a lens for adjusting a detection angle of electrons scattered in a sample during obtaining a STEM image.

According to the graph of FIG. 5A, the brightness difference in the STEM image of the standard sample 101 is the largest at the detection angle adjustment lens current of 0.5 A. Based on the graph of FIG. 5A, therefore, by adjusting the detection angle adjustment lens current, which is one of the observation conditions to be applied to the observation sample 102, the brightness difference between two phases contained in the STEM image of the observation sample 102 can be maximized.

The graph shown in FIG. 5B includes data showing the respective relationships between the brightness and the detection angle adjustment lens current in Phase A, Phase B, Phase C, and Phase D contained in the STEM image of the standard sample 101. The graph in FIG. 5B indicates that the brightness of each phase changes with a change in the detection angle adjustment lens current and change characteristics of the brightness are different for each phase.

The graph such as FIG. 5B obtained using the standard sample 101 can be used for the analysis of the observation image of the observation sample 102. For example, it is possible to distinguish which of the regions of the observation sample 102 correspond to Phases A through D, respectively by comparing the brightness of the STEM image of the observation sample 102 obtained at the detection angle adjustment lens current of 0.7 A with the brightness at the detection angle adjustment lens current of 0.7 A in FIG. 5B. Further, when the composition of a material constituting each phase contained in the standard sample 101 is known, it is possible to find the composition of each region in the STEM image of the observation sample 102 by comparing the graph of FIG. 5B with the brightness of the STEM image of the observation sample 102.

The embodiments of the present invention were described above. Both a TEM image and a STEM image can be obtained using TEM. Although the description herein is mainly for the case of using the STEM image, but the content of the present invention is applicable even if the TEM image is used. In addition, the present invention is not limited to the above-described embodiments, but can be materialized by modifying the constituents without departing from the gist of the present invention. It is also possible to use a plurality of constituents disclosed in the above embodiments in combination as needed. Further, some constituents may be deleted from all the constituents shown in the above-described embodiments.

### LIST OF REFERENCE SIGNS

101: standard sample
101a: upper surface
101b: side surface
102: observation sample
103: sample holder
201: protection film
202: film stack
301: focused ion beams
302: metal probe
303: sample piece
401: observation surface
402: orthogonal plane

1. A standard sample for use in a transmission electron microscope, comprising:
a film stack that is formed by stacking a plurality of materials on a surface of an observation sample to be observed with the transmission electron microscope; and
an observation surface that is a plane intersecting the surface of the observation sample and being connected to the observation sample.

2. The standard sample according to claim 1, wherein
the film stack is prepared by stacking a plurality of materials having average atomic numbers relatively close to each other, respectively.

3. The standard sample according to claim 2, wherein
the materials to be stacked as the film stack are the same as materials contained in the observation sample.

4. A method of preparing a standard sample for use in a transmission electron microscope, comprising:
a stacking step in which a plurality of materials is stacked on a surface of an observation sample to be observed with a transmission electron microscope;
an observation surface formation step in which an observation surface that is a plane intersecting the surface of the observation sample and being connected to the observation sample is formed; and
a film thinning step in which a thickness in a direction orthogonal to the observation surface is thinned.

5. The method according to claim 4, wherein
in the stacking step, a plurality of materials respectively having average atomic numbers relatively close to each other are stacked one after another.

6. The method according to claim 5, wherein
in the stacking step, the plurality of materials contained in the observation sample are stacked one after another.

7. The method according to claim 4, wherein
in the stacking step, an atomic layer deposition device is used.

8. The method according to claim 4, wherein
in the stacking step, focused ion beams are used.

9. The method according to claim 4, wherein
in the film thinning step, focused ion beams are used.

10. A method of adjusting a transmission electron microscope, comprising:
adjusting observation conditions to be used for observing an observation sample based on data obtained using a standard sample comprising
a film stack that is formed by stacking a plurality of materials on a surface of an observation sample to be observed with the transmission electron microscope; and
an observation surface that is a plane intersecting the surface of the observation sample and being connected to the observation sample.

11. A method of analyzing an observation image obtained using a transmission electron microscope, comprising:
carrying out distinguishment or composition determination of a plurality of regions contained in an observation image of the observation sample based on data obtained using a standard sample comprising
a film stack that is formed by stacking a plurality of materials on a surface of an observation sample to be observed with the transmission electron microscope; and
an observation surface that is a plane intersecting the surface of the observation sample and being connected to the observation sample.
